(19) United States
(12) Patent Application Publication
(10) Pub. No.: US 2026/0348010 A1
(43) Pub. Date: Nov. 5, 2026

(54) GAS SUPPLY METHOD, METHOD OF MANUFACTURING SEMICONDUCTOR DEVICE, SUBSTRATE PROCESSING APPARATUS, RECORDING MEDIUM, AND FLOW RATE CONTROLLER

(71) Applicant: Kokusai Electric Corporation, Tokyo (JP)

(72) Inventor: Shoki TANAKA, Toyama-shi (JP)

(73) Assignee: Kokusai Electric Corporation, Tokyo (JP)

(21) Appl. No.: 19/719,445

(22) Filed: Jun. 25, 2026

Related U.S. Application Data
(63) Continuation of application No. PCT/JP2023/047106, filed on Dec. 27, 2023.

(51) Int. Cl. C23C 16/455; C23C 16/44; H10P 72/00

(52) U.S. Cl. CPC C23C 16/45557; C23C 16/45561; C23C 16/45589; H10P 72/0402; H10P 72/0604; C23C 16/4412

(57) ABSTRACT

A technique is provided which includes: a first process of supplying a gas to a container while controlling a flow rate of the gas by regulating a degree of valve opening of a valve installed at a gas supply line; and a second process of supplying the gas to the container by regulating the degree of valve opening based on an internal pressure of the container.

### CROSS-REFERENCE TO RELATED APPLICATION

This application is a Bypass Continuation Application of PCT International Application No. PCT/JP2023/047106, filed on Dec. 27, 2023 and designating the United States, the entire contents of which are incorporated herein by reference.

### TECHNICAL FIELD

The present disclosure relates to a gas supply method, a method of manufacturing a semiconductor device, a substrate processing apparatus, a recording medium, and a flow rate controller.

### BACKGROUND

In the related art, as a step of a manufacturing process of a semiconductor device, when a substrate is supplied with a processing gas (e.g., a precursor gas, a reaction gas, or the like) to form a film on the substrate, a substrate processing step of supplying a large amount of processing gas accumulated in a tank (hereinafter, also referred to as a container) in an extremely short time at once may be performed.

### SUMMARY

The present disclosure provides a technique of filling a container with a large amount of processing gas.

According to some embodiments of the present disclosure, there is provided a technique that includes: a first process of supplying a gas to a container while controlling a flow rate of the gas by regulating a degree of valve opening of a valve installed at a gas supply line; and a second process of supplying the gas to the container by regulating the degree of valve opening based on an internal pressure of the container.

According to the present disclosure, a large amount of a processing gas may be charged in a container.

### BRIEF DESCRIPTION OF DRAWINGS

The accompanying drawings, which are incorporated in and constitute a part of the specification, illustrate embodiments of the present disclosure.

FIG. 1 is a schematic configuration diagram of a substrate processing apparatus suitably used in some embodiments of the present disclosure.

FIG. 2 is a cross-sectional view of line A-A of FIG. 1.

FIG. 3 is a schematic configuration diagram of a controller of a substrate processing apparatus suitably used in some embodiments of the present disclosure, and illustrates a control system of the controller in a block diagram.

FIG. 4 is a flowchart illustrating a film formation sequence in some embodiments of the present disclosure.

FIG. 5 is a diagram illustrating a precursor gas supply system in some embodiments of the present disclosure.

FIG. 6 is a flowchart illustrating switching control of a control mode in which a precursor gas is supplied into a tank in some embodiments of the present disclosure.

FIG. 7 is a view showing an example of a time course of an internal pressure of the tank and a degree of valve opening of a valve when a flow of FIG. 6 is executed.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Embodiments of the Present Disclosure

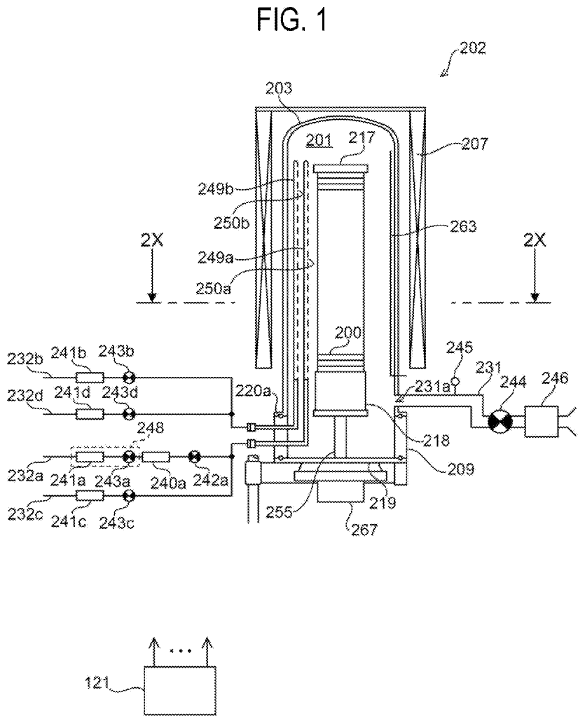

Hereinafter, some embodiments of the present disclosure will be described mainly with reference to FIGS. 1 to 7. In addition, the drawings used in the following description are schematic, and dimensional relationships, ratios, and the like of the respective components shown in the drawings may not match actual ones. Further, dimensional relationships, ratios, and the like of the respective components may not match one another among a plurality of drawings.

### (1) Configuration of Substrate Processing Apparatus

As shown in FIG. 1, a process furnace 202 includes a heater 207 as a temperature regulator (heating part). The heater 207 is formed in a cylindrical shape and is vertically installed by being supported by a holding plate. The heater 207 functions as an activator (an exciter) configured to activate (excite) a gas with heat. The heater 207 also functions as an energy applier configured to apply thermal energy to a substrate.

A reaction tube 203 is disposed inside the heater 207 to be concentric with the heater 207. The reaction tube 203 is made of, for example, a heat resistant material such as quartz (SiO₂) or silicon carbide (SiC), and is formed in a cylindrical shape with its upper end closed and its lower end opened. A manifold 209 is disposed to be concentric with the reaction tube 203 under the reaction tube 203. The manifold 209 is constituted by, for example, a metal material such as stainless steel (SUS), and formed in a cylindrical shape with both of its upper and lower ends opened. The upper end of the manifold 209 engages with the lower end of the reaction tube 203 so as to support the reaction tube 203. An O-ring 220a serving as a seal is provided between the manifold 209 and the reaction tube 203. Similar to the heater 207, the reaction tube 203 is vertically installed. A process container (reaction container) mainly includes the reaction tube 203 and the manifold 209. A process chamber 201 is formed in a hollow cylindrical area of the process container. The process chamber 201 is configured to be capable of accommodating a plurality of wafers 200 as substrates. Processing on the wafers 200 is performed in the process chamber 201.

Nozzles 249a and 249b as first and second suppliers are installed in the process chamber 201 so as to penetrate a sidewall of the manifold 209. The nozzles 249a and 249b are also referred to as first and second nozzles, respectively. The nozzles 249a and 249b are made of, for example, a heat resistant material such as quartz or SiC. Gas supply pipes 232a and 232c are connected to the nozzles 249a and 249b, respectively. The nozzles 249a to 249b are different nozzles, and the nozzles 249a and 249b are installed adjacent to each other.

At the gas supply pipe 232a, a vaporizer 248, which includes a vaporization part 241a configured to vaporize a precursor into a gas (a precursor gas as a first processing gas) and a mass flow controller (MFC) 251 which is a flow rate controller (a flow rate control part) including a valve 243a as a first valve which is a piezoelectric valve, a storage 240a as an example of a container configured to be capable of temporarily storing the gas vaporized in the vaporizer 248, and a valve 242a as a second valve are installed sequentially from the upstream side of the gas flow. Further, a pressure sensor 247 is installed between the vaporizer 248 and the storage 240a. An internal pressure of the storage 240a may be detected by the pressure sensor 247. Hereinafter, in the present disclosure, the MFC 251 will be described as being included in the vaporizer 248, but the above-described vaporizer 248 is an example, and the MFC 251 may not be included in the vaporizer 248.

A gas supply pipe 232c is connected to the gas supply pipe 232a at the downstream side of the valve 242a. At the gas supply pipe 232c, the MFC 241c and the valve 243c are installed sequentially from the upstream side of the gas flow. The gas supply pipes 232a and 232c and the storage 240a are constituted by, for example, a metal material such as SUS. A precursor gas supply system (a precursor gas supply line) mainly includes the gas supply pipe 232a, the vaporizer 248 including the vaporization part 241a and the valve 243a, the storage 240a, and the valve 242a.

A flow path cross-sectional area of the storage 240a is larger than that of a normal pipe, and is constituted as, for example, a gas tank with a gas capacity larger than that of the normal pipe. By opening or closing the valve 243a at the upstream side of the storage 240a and the valve 242a at the downstream side of the storage 240a, a gas which is a precursor in a gas phase supplied from the gas supply pipe 232a may be charged in the storage 240a, or the gas charged in the storage 240a may be supplied into the process chamber 201. Further, the vaporizer 248 will be described in detail later.

A gas vaporized in the vaporization part 241a and regulated in flow rate at the MFC 251 by regulating the degree of valve opening of the valve 243a may be charged in the storage 240a by closing the valve 242a. Then, when the internal pressure of the storage 240a reaches a first predetermined pressure (hereinafter, may be referred to as a first predetermined value), the flow rate control in the MFC 251 switches to control of determining the degree of valve opening of the valve 243a based on the internal pressure of the storage 240a. Further, when a predetermined amount of gas is charged in the storage 240a, and the internal pressure of the storage 240a reaches a second predetermined pressure (hereinafter, may be referred to as a second predetermined value), the valve 243a is closed and the valve 242a is opened, whereby a high-pressure gas charged in the storage 240a can be supplied (flush-supplied) to the process chamber 201 via the gas supply pipe 232a and the nozzle 249a at once (in a short time). Further, a gas supply method in the precursor gas supply system (precursor gas supply line) will be described in detail later. Further, at the time of flush supply, the valve 243a may be opened.

At the gas supply pipe 232b, a MFC 241b and a valve 243b, which is an open/close valve, are installed sequentially from the upstream side of the gas flow, respectively. A gas supply pipe 232d is connected to the gas supply pipe 232b at the downstream side of the valve 243b. At the gas supply pipe 232d, the MFC 241d and the valve 243d are installed sequentially from the upstream side of the gas flow. The gas supply pipes 232b and 232d are made of, for example, a metal material such as SUS.

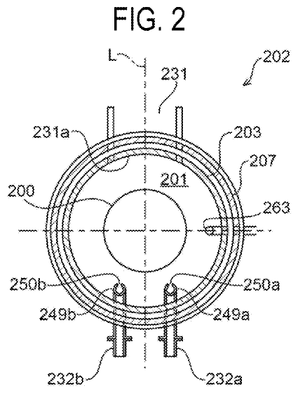

As shown in FIG. 2, each of the nozzles 249a and 249b is installed in an annular space (in plan view) between an inner wall of the reaction tube 203 and the wafers 200 so as to extend upward from a lower side to an upper side of the inner wall of the reaction tube 203, that is, along an arrangement direction of the wafers 200. Specifically, each of the nozzles 249a and 249b is installed in a region horizontally surrounding a wafer arrangement region in which the wafers 200 are arranged at a lateral side of the wafer arrangement region, along the wafer arrangement region. In plan view, the nozzle 249a is disposed so as to face an exhaust port 231a described below with centers of the wafers 200 loaded into the process chamber 201, which are interposed therebetween. The nozzle 249b is disposed adjacent to the nozzle 249a along the inner wall of the reaction tube 203 (an outer periphery of the wafer 200). Gas supply holes 250a and 250b configured to supply a gas are formed on the side surfaces of the nozzles 249a and 249b, respectively. Each of the gas supply holes 250a and 250b is opened so as to oppose (face) the exhaust port 231a in plan view, which enables a gas to be supplied toward the wafers 200. A plurality of gas supply holes 250a and 250b are formed from the lower side to the upper side of the reaction tube 203.

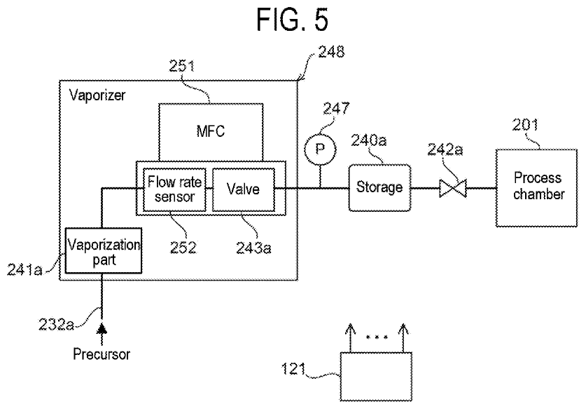

As shown in FIG. 5, the vaporizer 248 constituting the precursor gas supply system includes the vaporization part 241a, and the MFC 251 including a flow rate sensor 252 and the valve 243a. The vaporization part 241a is installed at a precursor supply line (in this case, at the gas supply pipe 232a). The vaporization part 241a serves to vaporize the precursor into the gaseous gas as described above. The MFC 251 is installed at the precursor supply line. Specifically, the MFC 251 is installed at the downstream side of the vaporization part 241a in the gas flow.

Further, the MFC 251 is configured to be capable of supplying the gas to the storage 240a while controlling the flow rate of the gas by regulating the degree of valve opening of the valve 243a installed at the supply line. Specifically, the MFC 251 includes the flow rate sensor 252 and the valve 243a. The flow rate sensor 252 is an example of a sensor, which is installed at the supply line and serves to detect a flow rate of a vaporized precursor (hereinafter, appropriately referred to as “gas”). In the embodiments of the present disclosure, as an example, the MFC 251 regulates the degree of valve opening of the valve 243a based on the flow rate detected by the flow rate sensor 252. The valve 243a is installed at the supply line and serves to supply the gas to the storage 240a. Specifically, supply and stop of gas to the storage 240a are switched by opening and closing the valve 243a.

The MFC 251 is configured to be capable of supplying the gas to the storage 240a while controlling the flow rate of the gas by regulating the degree of valve opening of the valve 243a based on the flow rate detected by the flow rate sensor 252 when a pressure value of the storage 240a is within a range of pressure in which the flow rate can be controlled.

Further, the MFC 251 is configured to be capable of regulating the degree of valve opening of the valve 243a based on the internal pressure of the storage 240a to supply the gas to the storage 240a when the pressure value of the storage 240a is outside the range of pressure in which the flow rate can be controlled. Specifically, in a case where the pressure value of the storage 240a is outside the range of pressure in which the flow rate can be controlled by MFC 251, the flow rate control by the MFC 251 is switched to the control of the degree of valve opening of the valve 243a by a controller 121. As described above, a system configured to switch between the flow rate control by the MFC 251 and the control of the degree of valve opening of the valve 243a by the controller 121 is referred to as a vaporization system in the embodiments. As shown in FIG. 5, the vaporization system is mainly constituted by the vaporizer 248 and the controller 121.

In addition, a certain degree of differential pressure is desired for the flow rate controllable condition of the MFC 251. Therefore, as the gas is charged in the storage 240a, the internal pressure of the storage 240a increases, and thus the differential pressure decreases, such that the control in the MFC 251 is close to a control limit. In the embodiments of the present disclosure, when the control limit is reached in the MFC 251, by switching from the flow rate control in the MFC 251 to the control of the degree of valve opening of the valve 243a by the controller 121, it is possible to increase an amount of the gas that can be charged in the storage 240a. In addition, when there is a certain degree of differential pressure as the flow rate controllable condition, the flow rate of the gas is controlled by the MFC 251 because vaporization amount>gas supply amount can be stably controlled. Herein, the vaporization amount refers to an amount of gas vaporized in the vaporization part 241a, and the gas supply amount refers to an amount of gas flowing through the valve 243a. In a case where a relationship between vaporization amount>gas supply amount is not maintained, a mixed gas of the liquid and the gas is likely to flow to the storage 240a and become a particle source. Therefore, the MFC 251 is configured to regulate the degree of valve opening of the valve 243a so as to maintain the relationship of vaporization amount>gas supply amount. In addition, since an operation amount of the valve 243a is controlled based on the flow rate sensor 252 immediately near the valve 243a, it is estimated that both responsiveness and accuracy will be much improved by controlling the operation amount of the valve 243a based on the internal pressure of the storage 240a.

From the gas supply pipe 232b, the reaction gas as the second processing gas is supplied to the process chamber 201 via the MFC 241b, the valve 243b, and the nozzle 249b. Further, the reaction gas is a substance whose molecular structure (chemical structure) is different from that of the precursor gas.

From the gas supply pipes 232c and 232d, an inert gas is supplied to the process chamber 201 via the MFCs 241c and 241d, the valves 243c and 243d, the gas supply pipes 232a and 232b, and the nozzles 249a and 249b, respectively. The inert gas acts as a purge gas, a carrier gas, a dilution gas, or the like.

A reaction gas supply system (a reaction gas supply line) mainly includes the gas supply pipe 232b, the MFC 241b, and the valve 243b. An inert gas supply system (an inert gas supply line) mainly includes the gas supply pipes 232c and 232d, the MFCs 241c and 241d, and the valves 243c and 243d.

Each or both of the precursor gas and the reaction gas is also referred to as a film formation gas, and each or both of the precursor gas supply system and the reaction gas supply system is also referred to as a film formation gas supply system (a film formation gas supply line).

Further, the inert gas supply system (the inert gas supply line) constituted by the gas supply pipe 232c, the MFC 241c, and the valve 243c may be included in the precursor gas supply system, and the inert gas supply system (the inert gas supply line) constituted by the gas supply pipe 232d, the MFC 241d, and the valve 243d may be included in the reaction gas supply system.

Further, open/close operations of the valve 243a included in the vaporizer 248, and the valve 242a, 243b, 243c, and 243d, and flow rate regulating operation by the MFCs 241b, 241c, and 241d, and the like are controlled by the controller 121 to be described later.

The exhaust port 231a configured to exhaust an atmosphere of the process chamber 201 is installed below the sidewall of the reaction tube 203. An exhaust pipe 231 is connected to the exhaust port 231a. The exhaust pipe 231 is constituted by, for example, a metal material such as stainless steel (SUS). A vacuum pump 246 as a vacuum exhauster, is connected to the exhaust pipe 231 via a pressure sensor 245, which is a pressure detector (pressure detection part) configured to detect a pressure of the process chamber 201, and an auto pressure controller (APC) valve 244, which is a pressure regulator (pressure regulation part). The APC valve 244 is configured to be capable of performing or stopping a vacuum exhausting operation in the process chamber 201 by opening or closing the valve while the vacuum pump 246 is actuated, and is also configured to be capable of regulating the pressure of the process chamber 201 by adjusting a degree of valve opening based on pressure information detected by the pressure sensor 245 while the vacuum pump 246 is actuated. An exhaust system mainly includes the exhaust pipe 231, the APC valve 244, and the pressure sensor 245. The vacuum pump 246 may be included in the exhaust system.

A seal cap 219, which serves as a furnace opening lid (hereinafter, referred to as a lid) configured to be capable of hermetically sealing a lower end opening of the manifold 209, is installed under the manifold 209. The lid 219 is made of, for example, a metal material such as SUS, and is formed in a disc shape. An O-ring 220b, which is a seal making contact with the lower end of the manifold 209, is installed on an upper surface of the lid 219. A rotator 267 configured to rotate a boat 217, which is described below, is installed under the lid 219. A rotary shaft 255 of the rotator 267 is constituted by, for example, a metal material such as SUS, and connected to the boat 217 through the lid 219. The rotator 267 is configured to rotate the wafers 200 by rotating the boat 217. The lid 219 is configured to be vertically moved up or down by a boat elevator 115 which is an elevator installed outside the reaction tube 203. The elevator 115 is constituted as a transfer apparatus (transfer mechanism) configured to load or unload (transfer) the wafers 200 into or out of the process chamber 201 by moving the lid 219 up or down.

The boat 217 serving as a substrate support is configured to support a plurality of wafers 200, for example, 25 to 200 wafers, in such a state that the wafers 200 are arranged in a horizontal posture and in multiple stages along a vertical direction with the centers of the wafers 200 aligned with one another, i.e., to be arranged at intervals. Heat insulating plates 218 constituted by, for example, a heat resistant material such as quartz or SiC are installed in multiple stages at a lower side of the boat 217.

A temperature sensor 263 serving as a temperature detector is installed in the reaction tube 203. Based on temperature information detected by the temperature sensor 263, a state of supplying electric power to the heater 207 is regulated such that a temperature distribution in the process chamber 201 becomes a desired temperature distribution. The temperature sensor 263 is installed along the inner wall of the reaction tube 203.

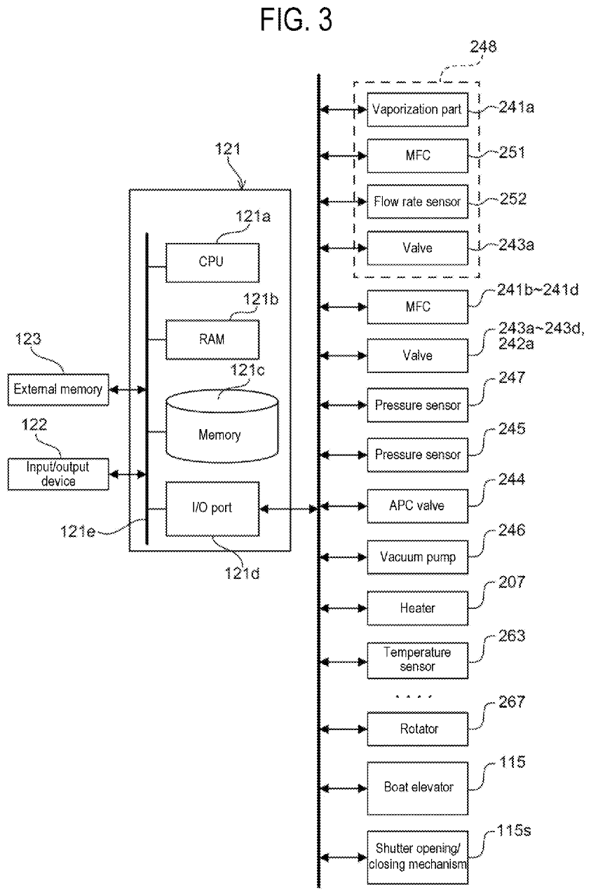

As shown in FIG. 3, a controller 121, which is a control part (control means or unit), is constituted as a computer including a central processing unit (CPU) 121a, a random access memory (RAM) 121b, a memory 121c, and an I/O port 121d. The RAM 121b, the memory 121c, and the I/O port 121d are configured to be capable of exchanging data with the CPU 121a via an internal bus 121e. An input/output device 122 constituted as, e.g., a touch panel or the like, is connected to the controller 121.

The memory 121c is constituted by, for example, a flash memory, a hard disk drive (HDD), a solid state drive (SSD), or the like. A control program to control operations of a substrate processing apparatus, a process recipe in which sequences and conditions of a substrate processing process which is described below are written, etc. are readably recorded and stored in the memory 121c. The process recipe functions as a program that is combined to cause the controller 121 to execute each sequence in a substrate processing process (an etching process, etc.), which is described below, to obtain an expected result. Hereinafter, the process recipe and the control program may be generally and simply referred to as a “program.” Further, the process recipe may be simply referred to as a “recipe.” When the term “program” is used herein, it may indicate a case of including the recipe, a case of including the control program, or a case of including both the recipe and the control program. The RAM 121b is constituted as a memory area (work area) in which programs or data read by the CPU 121a are temporarily stored.

The I/O port 121d is connected to the MFCs 251, 241b, 241c, and 241d, the valves 243a, 242a, 243b, 243c, and 243d, the vaporization part 241a, the pressure sensors 245 and 247, the APC valve 244, the vacuum pump 246, the temperature sensor 263, the heater 207, the rotator 267, the elevator 115, and so on.

The CPU 121a is configured to be capable of reading and executing the control program from the memory 121c. The CPU 121a is also configured to be capable of reading the recipe from the memory 121c according to an input of an operation command from the input/output device 122. The CPU 121a is configured to be capable of controlling flow rate regulating operations of various kinds of gases by the MFCs 251, 241b, 241c, and 241d, opening/closing operations of the valves 243a and 242a and valves 243b, 243c, and 243d, precursor vaporization operation (also referred to as a heating operation) by the vaporization part 241a, opening/closing operation of the APC valve 244 and pressure regulating operation performed by the APC valve 244 based on the pressure sensor 245, actuating/stopping operation of the vacuum pump 246, temperature regulating operation performed by the heater 207 based on the temperature sensor 263, operations of rotating the boat 217 and adjusting a rotation speed of the boat 217 with the rotator 267, operation of moving the boat 217 up or down by the boat elevator 115, and so on, according to contents of the read recipe.

The controller 121 may be configured by installing, on the computer, the aforementioned program stored in the external memory 123. Examples of the external memory 123 may include a magnetic disk such as a HDD, an optical disc such as a CD, a magneto-optical disc such as a MO, a semiconductor memory such as a USB memory or a SSD, and the like. The memory 121c or the external memory 123 is constituted as a computer-readable recording medium. Hereinafter, the memory 121c and the external memory 123 may be generally and simply referred to as a “recording medium.” When the term “recording medium” is used herein, it may indicate a case of including the memory 121c, a case of including the external memory 123, or a case of including both the memory 121c and the external memory 123. Further, the program may be provided to the computer by using communication means or unit such as the Internet or a dedicated line, instead of using the external memory 123.

### (2) Substrate Processing Process

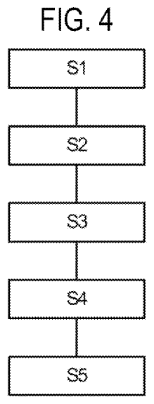

An example of a sequence in which processing is performed on the wafer 200 as a substrate, that is, an example of film formation sequence example in which a film is formed on the wafer 200, is mainly described by using FIG. 4 as a process of a manufacturing a semiconductor device by using the above-described substrate processing apparatus. In the following description, operation of each component constituting the substrate processing apparatus is configured to be capable of being controlled by the controller 121.

In the film formation sequence in the embodiments, a film is formed on the wafer 200 by performing a cycle including step A of supplying the precursor gas from the precursor gas supply line to the process chamber 201 in which the wafer 200 is accommodated and Step B of supplying the reaction gas to the process chamber 201 in which the wafer 200 is accommodated a predetermined number of times (n times, n is an integer of 1 or more).

Further, in the film formation sequence in the embodiments, when the precursor gas is supplied, the precursor gas is charged in advance into the storage 240a installed at the precursor gas supply line and then supplied to the process chamber 201. However, the supply method may be appropriately selected in accordance with the sequence such that the precursor gas is supplied to the process chamber 201 without being charged in advance into the storage 240a.

Further, in the film formation sequence in the embodiments, when step A and step B are alternately performed n times (n is an integer of 1 or more), a step of purging the process chamber 201 may be performed therebetween. Herein, “purge” refers to removal of a precursor gas or an intermediate present in the process chamber 201 by supplying an inert gas to the process chamber 201. “Exhaust” means removing a precursor gas or an intermediate present in the process chamber 201 without supplying an inert gas to the process chamber 201.

The term “wafer” used in the present disclosure may refer to a wafer itself or a stacked body of a wafer and a predetermined layer or film formed on a surface of the wafer. When the phrase “a surface of a wafer” is used herein, it may refer to a surface of a wafer itself or a surface of a predetermined layer or the like formed on a wafer. When the expression “a predetermined layer is formed on a wafer” is used herein, it may mean that a predetermined layer is directly formed on a surface of a wafer itself or that a predetermined layer is formed on a layer or the like formed on a wafer. Further, the term “substrate” used in the present disclosure may be synonymous with the term “wafer.”

### Substrate Loading S1: Wafer Charging and Boat Loading

After the boat 217 is charged with a plurality of wafers 200 (wafer charging), the shutter 219s is moved by the shutter opening/closing mechanism 115s and the lower end opening of the manifold 209 is opened (shutter opening). Thereafter, as shown in FIG. 1, the boat 217 supporting the plurality of wafers 200 is lifted up by the boat elevator 115 to be loaded into the process chamber 201 (boat loading). In this state, the seal cap 219 seals the lower end of the manifold 209 via the O-ring 220b.

### Pre-Processing S2: Pressure Regulation and Temperature Regulation

After the boat loading is completed, the inside of the process chamber 201, that is, a space where the wafers 200 are placed, is vacuum-exhausted (evacuated/decompressed) by the vacuum pump 246 so as to reach a desired pressure (degree of vacuum). In this operation, a pressure of the process chamber 201 is measured by the pressure sensor 245, and the APC valve 244 is feedback-controlled based on the measured pressure information (pressure regulation). Further, the wafer 200 in the process chamber 201 is heated by the heater 207 to reach a desired processing temperature. At this time, a state of supplying electric power to the heater 207 is feedback-controlled based on the temperature information detected by the temperature sensor 263 such that a temperature distribution in the process chamber 201 becomes a desired temperature distribution (temperature regulation). Further, the rotation of the wafer 200 by the rotator 267 is started. The exhaust of the process chamber 201 and the heating and rotation of the wafer 200 are continuously performed at least until the processing on the wafer 200 is completed.

### Substrate Process S3: Film Formation Process

Then, the following steps A and B are sequentially performed.

### Step A

In this step, the precursor gas is supplied to the wafer 200 in the process chamber 201. First, the valve 242a is in a closed state, and the valve 243a is opened to supply the precursor gas to the storage 240a while controlling the flow rate of the precursor gas by regulating the degree of valve opening of the valve 243a (first process). Then, the degree of valve opening of the valve 243a is regulated based on the internal pressure of the storage 240a to supply the precursor gas to the storage 240a (second process).

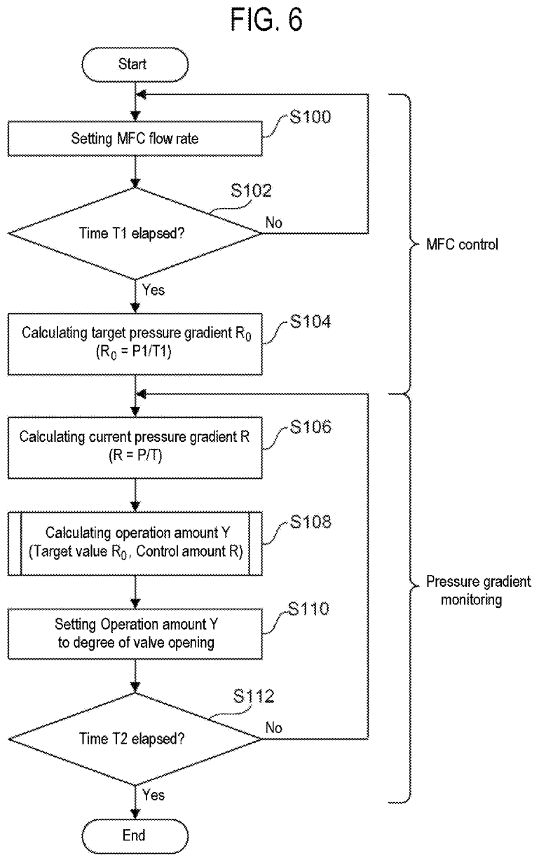

First, the first process will be described. The first process is a process including steps S100, S102, and S104 shown in FIG. 6. Further, in the first process, the supply of the gas to the storage 240a is controlled by the MFC 251.

In step S100, a flow rate of the precursor gas in the MFC 251 is set. Further, the flow rate regulation of the precursor gas in the MFC 251 is performed by regulating the degree of valve opening of the valve 243a. Further, the flow rate control in the MFC 251 may be controlled such that, for example, the flow rate becomes constant.

In step S102, it is determined whether a preset time T1 elapses. In this operation, in a case where the time T1 elapses, the process proceeds to step S104. On the other hand, in a case where the time T1 does not elapse, the process returns (proceeds) to step S100.

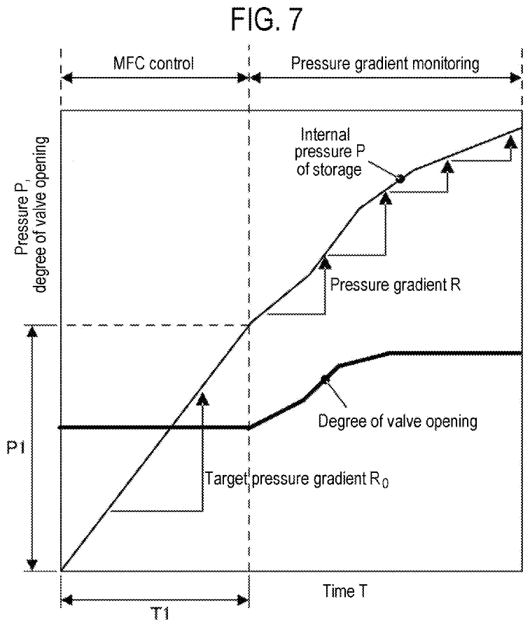

In step S104, a target pressure gradient R₀ is calculated. Specifically, as shown in FIG. 7, a time T1 and a pressure P1 within a range controlled by the MFC 251 are obtained, and the target pressure gradient R₀ is calculated from the time T1 and the pressure P1. The calculated target pressure gradient R₀ is stored in the RAM 121b or the memory 121c. Further, the target pressure gradient R₀ can be obtained by R₀=P1/T1.

Further, in FIG. 7, the vertical axis represents an internal pressure P of the storage 240a and a degree of valve opening of the valve 243a, and the horizontal axis represents a time T.

In this way, the first process ends. When the first process ends, the process proceeds to the second process. That is, in the embodiments, the process proceeds in the order of the first process and the second process. Further, the present disclosure is not limited to this configuration. For example, when a pressure difference with the storage 240a to which the gas is supplied is reduced and the valve 243a is brought into a closed state, the process may proceed from the first process to the second process. Further, for example, in the first process, when an internal pressure value of the storage 240a, that is, a pressure value detected by the pressure sensor 247, reaches a first predetermined value (for example, the pressure P1), the process may proceed from the first process to the second process. Further, for example, in the first process, when the internal pressure value of the storage 240a converges to the first predetermined value, the process may proceed to the second process.

Next, a second process will be described. The second process is a process including steps S106, S108, S110, and S112 shown in FIG. 6. Further, in the second process, the gas supply to the storage 240a is controlled by the controller 121.

First, when the process proceeds from the first process to the second process, the degree of valve opening the valve 243a is regulated to a preset degree of valve opening.

In step S106, a current pressure gradient R is calculated. Specifically, as shown in FIG. 7, the time T and the pressure P within the range controlled by the controller 121 are obtained, and the pressure gradient R is calculated from the time T and the pressure P. The calculated pressure gradient R is stored in the RAM 121b or the memory 121c. Further, the pressure gradient R can be obtained by R=P/T.

In step S108, an operation amount Y is calculated from the target value (the target pressure gradient) R₀ and the control amount (the pressure gradient) R.

In step S110, the calculated operation amount Y is set to the degree of valve opening of the valve 243a. That is, in the second process, the degree of valve opening of the valve 243a is changed based on the internal pressure of the storage 240a. Then, by setting the degree of valve opening of the valve 243a to the operation amount Y, the flow rate of the gas to the storage 240a is regulated. Further, regulation of the degree of valve opening of the valve 243a may be set a plurality of times during the second process.

Further, the operation amount Y may be set such that the pressure gradient R in the second process is equal to or less than the target pressure gradient R₀ in the first process.

In step S112, it is determined whether the preset time T2 elapses. In this operation, when the time T2 elapses, the second process ends. Further, the present disclosure is not limited to this configuration. For example, the second process may be performed until the internal pressure value of the storage 240a becomes a second predetermined value larger than the first predetermined value, or may be performed until the internal pressure value of the storage 240a converges at the second predetermined value for a preset time. When the time T2 does not elapse, the process returns (proceeds) to step S106.

After the second process ends, the valve 243a is closed to maintain a state in which the precursor gas is charged in the storage 240a.

Further, in the embodiments, a third process may be performed after the second process. The third process is a step of supplying the gas from the storage 240a to the process chamber 201 by opening the valve 242a as a supply valve installed at the downstream side of the storage 240a. In the embodiments, as an example, when the internal pressure value of the storage 240a becomes the second predetermined value, the process proceeds from the second process to the third process.

In the third process, the valve 242a is opened, and a high-pressure precursor gas charged in the storage 240a flows into the process chamber 201 at once. As a result, the precursor gas is supplied to the wafer 200 at once (flush supply of the precursor gas). In this operation, the valves 243c and 243d may be opened to supply an inert gas to the process chamber 201 via the nozzles 249a and 249b, respectively. In addition, this step may be performed in a state where the exhaust system is substantially fully closed (the APC valve 244 is substantially fully closed). In this case, a state of being substantially blocked (a state of substantially fully closed) includes a state where the APC valve 244 is open by approximately 0.1% to several percent, or a state where even when the APC valve 244 is controlled to be closed by 100%, exhaust may be performed by the exhaust system due to performance of the APC valve 244.

Then, the valves 243a and 242a are closed, and the supply of the precursor gas to the process chamber 201 is stopped. Then, the APC valve 244 is made to be, for example, fully opened to vacuum-exhaust the process chamber 201, thereby removing gas or the like remaining in the process chamber 201 from the process chamber 201.

Further, in the above-described second process, the degree of valve opening of the valve 243a is set a plurality of times during the second process, but the present disclosure is not limited thereto. For example, the degree of valve opening of the valve 243a may be set to a predetermined degree of valve opening during the second process.

Further, in the above-described step A, after the first process is performed for time T1, the second process is performed for time T2, but the present disclosure is not limited thereto. For example, the first process may be performed when the internal pressure value of the storage 240a is within the range of pressure in which the flow rate can be controlled by the MFC 251, and the second process may be performed when the internal pressure value of the storage 240a is outside the range of pressure in which the flow rate can be controlled by the MFC 251.

Further, when the third process ends, the valves 243a and 242a may be closed to perform the first process or the second process.

### Step B

After step A ends, the reaction gas is supplied to the wafer 200 of the process chamber 201, that is, a first layer formed on the wafer 200, for example, a precursor element-containing layer.

Specifically, the valve 243b is opened to allow the reaction gas to flow through the gas supply pipe 232b. The reaction gas is regulated in flow rate by the MFC 241b to be supplied to the process chamber 201 via the nozzle 249b, and is exhausted from the exhaust port 231a. At this time, the reaction gas is supplied to the wafer 200 (supply of reaction gas). At this time, the valves 243c and 243d may be opened to supply an inert gas to the process chamber 201 via the nozzles 249a and 249b, respectively.

In a case where, for example, a nitriding gas to be described later is used as the reaction gas, at least a portion of the first layer formed on the wafer 200 is nitrided (modified) by supplying the nitriding gas to the wafer 200 under processing conditions to be described later. As a result, a nitride layer as the second layer is formed on an outermost surface of the wafer 200 as the base.

After the second layer is formed, the valve 243b is closed to stop supply of the nitriding gas to the process chamber 201. Then, by a processing procedure similar to that of the purge in step A, gas or the like remaining in the process chamber 201 is removed from the process chamber 201 (purge).

### Performing Predetermined Number of Times

A film can be formed on the surface of the wafer 200 by performing a cycle including the above-described steps A and B a predetermined number of times (n times, n is an integer of 1 or more). The above-described cycle may be performed a plurality of times. That is, a thickness of a layer formed per cycle is made smaller than a desired film thickness, and the above-described cycle may be performed a plurality of times until a thickness of a film formed by stacking the layers reaches the desired thickness. At this time, in step A, an amount of the precursor gas to be charged in advance into the storage 240a may be set to be a constant amount for each cycle. Further, in the second and subsequent cycles, the charging of the precursor gas in the storage 240a in step A may be performed concurrently with the supply of the reaction gas in step B of the previous cycle.

### Post-Processing S4: After-Purge and Returning to Atmospheric Pressure

After film formation of a desired thickness on the wafer 200 is completed, an inert gas as a purge gas is supplied to the process chamber 201 from each of the nozzle 249a and the nozzle 249b, and is exhausted via the exhaust port 231a. As a result, the process chamber 201 is purged, and a gas, a reaction by-product, or the like remaining in the process chamber 201 is removed from the process chamber 201 (after purge). Thereafter, the atmosphere of the process chamber 201 is substituted with an inert gas (inert gas substitution), and the pressure of the process chamber 201 is returned to a normal pressure (returning to atmospheric pressure).

### Substrate Unload S5: Boat Unloading and Wafer Discharging

Thereafter, the lid 219 is moved down by the elevator 115 to open the lower end of the manifold 209. Then, the processed wafers 200 supported by the boat 217 are unloaded from the lower end of the manifold 209 to the outside of the reaction tube 203 (boat unloading). After the boat unloading, the shutter 219s is moved and the lower end opening of the manifold 209 is sealed by the shutter 219s via the O-ring 220c (shutter closing). The processed wafers 200 are unloaded to the outside of the reaction tube 203, and then discharged from the boat 217 (wafer discharging).

### (4) Effect of the Present Aspect

According to the embodiments of the present disclosure, one or more effects shown below are obtained.
(a) According to the embodiments of the present disclosure, by a combination of the flow rate control by the MFC 251 and the control of degree of valve opening of the valve 243a by the controller 121, a greater more amount of gas than the amount of gas that can be charged in the storage 240a by the flow rate control by the MFC 251 can be stored in the storage 240a. This makes it possible to supply a gas with a large flow rate to the process chamber 201 at once.
(b) According to the embodiments of the present disclosure, the gas can be stored in the storage 240a even in a case where the gas cannot be charged in the storage 240a by the flow rate control by the MFC 251 or even in a case where the pressure of the container (tank) rises and the flow rate control by the MFC 251 cannot be performed (when the pressure of the container is out of the range of pressure in which the flow rate can be controlled by the MFC 251). This makes it possible to supply a gas with a large flow rate to the process chamber 201 at once.
(c) According to the embodiments of the present disclosure, since the degree of valve opening of the valve 243a is determined such that the pressure gradient is smaller than that when the gas subjected to the flow rate control by the MFC 251 is being charged in the storage 240a, liquefaction of the gas due to pressure change in the storage 240a can be suppressed.
(d) According to the embodiments of the present disclosure, since the gas subjected to the flow rate control by the MFC 251 is charged into the storage 240a, the gas can be charged in the storage 240a while always maintaining a relationship of vaporization amount>gas supply amount. In particular, at an initial stage, a differential pressure between the vaporization part 241a and the storage 240a is large, and the degree of valve opening of the valve 243a varies up and down, but the relationship of vaporization amount>gas supply amount can be maintained. Therefore, the gas in the liquid phase can be suppressed from flowing to the storage 240a, and the vaporized gas can be accumulated in the storage 240a, such that the vaporized gas can be stably flush-supplied to the wafer 200.
(e) According to the embodiments of the present disclosure, by varying the degree of valve opening of the valve, the pressure gradient can be adjusted, such that liquefaction due to the pressure change can be suppressed. Therefore, the gas in the liquid phase can be suppressed from flowing to the storage 240a, and the vaporized gas can be accumulated in the storage 240a, such that the vaporized gas can be stably flush-supplied to the wafer 200.
(f) According to the embodiments of the present disclosure, in step A, the precursor gas is charged in the storage 240a installed at the precursor gas supply line in advance for the wafer 200, and then supplied to the process chamber 201. That is, flush supply is performed. This makes it possible to uniformly adsorb a first intermediate (for example, SiCl₂ in a case where the precursor gas is a HCDS gas) over an entire surface of the wafer 200, and also to suppress adsorption of a second intermediate (for example, SiCl₄ in a case where the precursor gas is the HCDS gas) on the surface of the wafer 200. For this reason, it becomes possible to improve step coverage of the film formed on the wafer 200 and uniformity of film thickness on a substrate surface. As a result, quality of the film formed on the wafer 200 can be improved, and a yield can be increased.
(g) According to the embodiments of the present disclosure, in step A, when the precursor gas is supplied, the precursor gas is supplied to the process chamber 201 in a state in which the exhaust system configured to exhaust the atmosphere of the process chamber 201 is substantially closed, that is, in a state in which the exhaust system is substantially completely closed. As a result, it is possible to rapidly increase the pressure of the process chamber 201, thereby increasing the pressure in a short time to a predetermined pressure to adsorb the first intermediate on the entire surface of the wafer 200. This makes it possible to shorten a cycle time, thereby improving productivity of the film formation process.

### Other Embodiments of the Present Disclosure

The embodiments of the present disclosure are specifically described above. However, the present disclosure is not limited to the above-described embodiments, and various changes may be made without departing from the spirit of the present disclosure.

Further, in the above-described embodiments, as the precursor gas, for example, a silane-based gas containing Si as a main element constituting a film formed on the wafer 200 may be used. As the silane-based gas, for example, a gas containing Si and halogen, that is, a halosilane gas may be used. The halogen includes chlorine (Cl), fluorine (F), bromine (Br), iodine (I), and the like. As the halosilane gas, for example, a chlorosilane gas containing Si and Cl may be used.

As the precursor gas, in addition to the above-described gases, for example, a gas containing Si and an amino group, i.e., an aminosilane gas, may be used. The amino group is a monovalent functional group from which hydrogen (H) is removed from ammonia, a primary amine, or a secondary amine, and may be represented as —NH₂, —NHR, and —NR₂. Further, R represents an alkyl group, and two R's of —NR₂ may be the same or different.

Further, the present disclosure can be applied to a case where a film containing a metal element such as an aluminum nitride film (AlN film), a titanium nitride film (TiN film), a hafnium nitride film (HfN film), a zirconium nitride film (ZrN film), a tantalum nitride film (TaN film), a molybdenum nitride film (MoN film), a tungsten nitride film (WN), an aluminum oxide film (AlO film), a titanium oxide film (TiO film), a hafnium oxide film (HfO film), a zirconium oxide film (ZrO film), a tantalum oxide film (TaO film), a molybdenum oxide film (MoO), a tungsten oxide film (WO), a titanium oxynitride film (TiON film), a titanium aluminum carbonitride film (TiAlCN film), a titanium aluminum carbide film (TiAlC film), and a titanium carbonitride film (TiCN film) is formed on a substrate, by using a precursor gas containing, for example, a metal element such as aluminum (Al), titanium (Ti), hafnium (Hf), zirconium (Zr), tantalum (Ta), molybdenum (Mo), tungsten (W), etc. and using the above-described film formation sequence. Even in such a case, at least some of the effects described in the above-described embodiments are obtained.

As the reaction gas, for example, a nitrogen (N)- and hydrogen (H)-containing gas which is a nitriding gas (a nitriding agent) may be used. The N- and H-containing gas is a N-containing gas and is also a H-containing gas. The N- and H-containing gas may contain a N—H bond.

Further, as the reaction gas, for example, a hydrogen nitride-based gas such as an ammonia (NH₃) gas, a diazene (N₂H₂) gas, a hydrazine (N₂H₄) gas, or a N₃H₈ gas may be used. As the reaction gas, one or more of these gases may be used.

Further, in the above-described embodiments, the present disclosure may be applied to a case where a film containing Si, such as a silicon nitride film (SiN film), a silicon carbonitride film (SiCN film), a silicon oxynitride film (SiON film), a silicon oxycarbide film (SiOC film), a silicon oxycarbonitride film (SiOCN film), a silicon boron carbonitride film (SiBCN film), a silicon boronitride film (SiBN film), a silicon oxide film (SiO film) is formed as a film formed on the wafer 200 in the substrate processing. Even in such a case, at least some of the effects described in the above-described embodiments are obtained.

The recipes mentioned above are not limited to newly-prepared ones but may be prepared, for example, by modifying existing recipes that are already installed in the substrate processing apparatus. Once the recipes are modified, the modified recipes may be installed in the substrate processing apparatus via a telecommunication line or a recording medium storing the recipes. In addition, the existing recipes already installed in the existing substrate processing apparatus may be directly modified by operating the input/output device 122 of the substrate processing apparatus.

An example in which a film is formed by using a batch-type substrate processing apparatus configured to process a plurality of substrates at a time is described in the above-described embodiments. The present disclosure is not limited to the above-described embodiments, but may be appropriately applied, for example, to a case where a film is formed by using a single-wafer type substrate processing apparatus configured to process a single substrate or several substrates at a time. In addition, an example in which a film is formed by using a substrate processing apparatus provided with a hot-wall-type process furnace is described in the above-described embodiments. The present disclosure is not limited to the above-described embodiments, but may be applied to a case where a film is performed by using a substrate processing apparatus provided with a cold-wall-type process furnace.

Even in the case of using these substrate processing apparatuses, each process may be performed according to the same processing procedures and processing conditions as those in the above-described embodiments and modifications, and the same effects as the above-described embodiments and modifications may be obtained.

The above-described embodiments and modifications may be used in proper combination. Processing procedures and processing conditions used in this case may be the same as, for example, the processing procedures and processing conditions in the above-described embodiments and modifications.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A gas supply method comprising:
a first process of supplying a gas to a container while controlling a flow rate of the gas by regulating a degree of valve opening of a valve installed at a gas supply line; and
a second process of supplying the gas to the container by regulating the degree of valve opening based on an internal pressure of the container.

2. The gas supply method of claim 1, wherein the gas supply method sequentially proceeds from the first process to the second process.

3. The gas supply method of claim 1, wherein the gas supply method proceeds to the second process when the valve is closed in the first process.

4. The gas supply method of claim 1, wherein the gas supply method proceeds to the second process when a value of the internal pressure of the container reaches a first predetermined value in the first process.

5. The gas supply method of claim 1, wherein the gas supply method proceeds to the second process when a value of the internal pressure of the container converges at a first predetermined value in the first process.

6. The gas supply method of claim 1, wherein upon proceeding from the first process to the second process, the degree of valve opening of the valve is set to a preset degree of valve opening.

7. The gas supply method of claim 6, wherein the preset degree of valve opening is set a plurality of times during the second process.

8. The gas supply method of claim 6, wherein the preset degree of valve opening is set to a constant degree of valve opening during the second process.

9. The gas supply method of claim 1, wherein in the second process, the degree of valve opening is changed based on the internal pressure of the container.

10. The gas supply method of claim 1, wherein a pressure gradient in the second process is set to be equal to or less than a pressure gradient in the first process.

11. The gas supply method of claim 5, wherein the second process is performed until the value of the internal pressure of the container becomes a second predetermined value greater than the first predetermined value.

12. The gas supply method of claim 11, wherein the second process ends when the value of the internal pressure of the container converges at the second predetermined value for a preset time.

13. The gas supply method of claim 12, further comprising a third process of supplying the gas from the container to a process chamber by opening a supply valve installed at a downstream side of the container,
wherein when the value of the internal pressure of the container becomes the second predetermined value, the gas supply method proceeds from the second process to the third process.

14. The gas supply method of claim 13, wherein when the third process ends, the supply valve is closed, such that the first process or the second process is performed.

15. The gas supply method of claim 14, wherein the first process is performed when the internal pressure of the container is within a range of pressure in which a flow rate controller is capable of controlling the flow rate, and
wherein the second process is performed when the internal pressure of the container is outside the range of pressure in which the flow rate controller is capable of controlling the flow rate.

16. A method of manufacturing a semiconductor device, comprising:
supplying the gas to a process chamber by using the gas supply method of claim 1.

17. A processing apparatus comprising:
a process chamber in which a substrate is processed;
a container installed at a supply line configured to supply a gas to the process chamber;
a flow rate controller configured to be capable of supplying the gas to the container while controlling a flow rate of the gas by regulating a degree of valve opening of a valve installed at the supply line; and
a controller configured to be capable of supplying the gas to the container by regulating the degree of valve opening based on an internal pressure of the container.

18. A non-transitory computer-readable recording medium storing a program that causes, by a computer, the processing apparatus of claim 17 to perform a process comprising:
supplying the gas to the container while controlling the flow rate of the gas by regulating the degree of valve opening of the valve installed at the supply line configured to supply the gas to the process chamber in which the substrate is processed; and
supplying the gas to the container by regulating the degree of valve opening based on the internal pressure of the container.

19. A flow rate controller used in the processing apparatus of claim 17, comprising:
a sensor configured to detect the flow rate of the gas.

20. The flow rate controller of claim 19, wherein the flow rate controller is configured to be capable of:
supplying the gas to the container while controlling the flow rate of the gas by regulating the degree of valve opening of the valve based on a flow rate detected by the sensor when the internal pressure of the container is within a range of pressure in which the flow rate controller is capable of controlling the flow rate, and
supplying the gas to the container by regulating the degree of valve opening of the valve based on the internal pressure of the container when the internal pressure of the container is outside the range of pressure in which the flow rate controller is capable of controlling the flow rate.
